(19) United States
(12) Patent Application Publication
(10) Pub. No.: US 2026/0062824 A1
(43) Pub. Date: Mar. 5, 2026

(54) SEPARATOR PLATE FOR AN ELECTROLYSER AND METHOD OF MANUFACTURING THE SEPARATOR PLATE

(71) Applicant: Reinz-Dichtungs-GmbH, Neu-Ulm (DE)

(72) Inventors: Luca BUMB, Neu-Ulm (DE); Brian HEATH, Ulm (DE); Andreas HELFENBEIN, Markt-Schwaben (DE); Wolfgang KRAUS, Neu-Ulm (DE); Jonas LEISCHER, Neu-Ulm (DE); Franz SCHWEIGGART, Pfaffenhofen (DE); Hans WALDVOGEL, Krumbach (DE); Stephan WENZEL, Pfaffenhofen (DE)

(21) Appl. No.: 18/820,119

(22) Filed: Aug. 29, 2024

(30) Foreign Application Priority Data
Jul. 7, 2023 (DE) 102023206455.3

(51) Int. Cl. C25B 13/02; B23K 26/354; C23C 14/22; C25B 13/05; C25B 13/08

(52) U.S. Cl. CPC C25B 13/02; B23K 26/354; C23C 14/22; C25B 13/05; C25B 13/08

(57) ABSTRACT

The present disclosure relates to a separator plate for an electrolyser, comprising a metal layer which has a surface structuring in sections, and an elastomer coating designed as a sealing element and applied to the metal layer for sealing at least one region of the separator plate. The surface structuring comprises a plurality of channel-shaped depressions produced by laser surface treatment. The elastomer coating is arranged at least in some regions on the surface structuring. The present disclosure additionally relates to a method for manufacturing the separator plate.

### CROSS-REFERENCE TO RELATED APPLICATION

This application claims priority to German Patent Application No. 10 2023 206 455.3, entitled “SEPARATOR PLATE FOR AN ELECTROLYSER AND METHOD OF MANUFACTURING THE SEPARATOR PLATE”, filed Jul. 7, 2023. The entire contents of the above-identified application is hereby incorporated by reference for all purposes.

### TECHNICAL FIELD

The present disclosure relates to a separator plate for an electrolyser and a method of manufacturing a separator plate for an electrolyser.

### BACKGROUND AND SUMMARY

Electrolysers produce, for example, hydrogen and oxygen from water by applying a potential and may at the same time compress at least one of the gases produced.

Conventional electrolysers often consist of a stack of individual cells, each of which has a sequence of layers with a separator plate, two media diffusion structures, in particular porous transport layer(s) (PTL) and/or gas diffusion layer(s) (GDL), and a membrane electrode assembly (MEA). This stack of electrochemical cells must be sealed off with respect to the exterior since the media are guided within the cells at an overpressure relative to the exterior pressure. To this end, electrolysers typically have, for each of the individual electrochemical cells stacked one above the other to form an electrolyser, a cell frame extending around the outer edge of the electrochemical cell. The individual cells in the stack are compressed together, for example by means of screws, between two end plates. Between the individual cell frames and between the cell frames and the separator plates or membrane electrode assemblies arranged between the cell frames, the stack of electrochemical cells has sealing elements extending circumferentially along the outer circumference, but usually at a distance inwards from the outer circumference.

The individual cells combined to form the stack are each separated by a separator plate, which serves on the one hand to separate the media and on the other hand to transmit the current or voltage from individual cell to individual cell, in particular by virtue of the webs between the fluid-guiding channels being in contact (possibly indirectly) with the MEAs. The separator plates often have on their surface a flow field with channel structures which are arranged to supply and discharge fluid. The flow field or the flow field's channel structures have the task of ensuring that media are distributed across the surface. Such separator plates are also called bipolar plates, as they simultaneously form an anode of a first cell and a cathode of a cell adjacent to the first cell.

The media, i.e. in many cases water, oxygen and hydrogen, are often supplied or discharged via through-openings formed in the separator plates. The through-openings of the separator plates in the stack are arranged in an overlapping manner so that they form fluid lines.

In an electrolyser, a pressure difference between the surrounding environment and the interior of an electrochemical cell may be more than 20 bar. For example, the pressure on the product side, for example the H₂ side, may be up to 40 bar, while the pressure on the reactant side, for example the H₂O side, is only up to 2 bar. It is therefore important to seal off the flow field with respect to the surrounding environment and also within the electrochemical system. A scaling element arranged around the flow field and/or a sealing element arranged around the through-opening is usually provided for this purpose.

Beads molded into the separator plates, elastomer seals molded onto a metal layer of the separator plate or combinations thereof are often used to seal the flow field and/or the through-openings. To avoid leaks, it is important that the elastomer seal is firmly bonded to the metal layer. To ensure that the elastomer seal adheres as well as possible to the metal layer of the separator plate, one surface of the metal layer is often treated with a single-layer adhesion promoter or a two-layer combination of primer and adhesion promoter before the elastomer seal is applied. Both primers and adhesion promoters usually consist of reactive polymers in a solvent mixture. As a rule, the metal layer is coated over its entire surface with the adhesion promoter and/or primer, for example in a solvent-containing bath, although only individual regions of the layer are provided with the elastomer and the layer only needs to be coated with adhesion promoter there. In addition, the bonding agent or primer in the active regions of the separator plate impairs the necessary electrical conductivity and would therefore often have to be removed again in the active regions, i.e. in the flow field.

There is therefore an ongoing need to seal the fluid-carrying regions of separator plates as well as possible from the environment or within the electrolyser. The present disclosure has been designed to solve the above problems at least in part.

According to a first aspect of the present disclosure, a separator plate for an electrolyser is provided. The separator plate comprises a metal layer which has a surface structuring in sections, wherein the surface structuring comprises a large number of channel-shaped depressions produced by laser surface treatment. In addition, the separator plate has an elastomer coating designed as a sealing element and applied to the metal layer to seal at least one region of the separator plate. The elastomer coating is arranged at least in some regions on the surface structuring.

In some embodiments, the surface structuring is designed to improve the adhesion of the elastomer coating to the metal layer. As a result of the improved adhesion, pre-treatment with an adhesion promoter and/or primer can be dispensed with, thus avoiding the use of environmentally harmful chemicals. In addition, the surface structuring formed as laser surface structuring can be precisely introduced into the material of the metal layer by a laser and, in particular, can be provided in the metal layer only where it is needed. The surface structuring can, for example, be provided only in the regions where the elastomer coating is present. Conversely, the elastomer coating can be located only in the regions of the surface structuring, wherein a lateral protrusion of the elastomer coating of up to 3 mm should be possible.

The separator plate can also have a PVD coating applied to the metal layer, with the elastomer coating being arranged on the PVD coating at least in some regions. PVD stands for “physical vapor deposition”. In general, PVD uses physical processes to convert a starting material into the gas phase. The gaseous material is then guided to the substrate to be coated—in this case the metal layer—where it condenses and forms the target layer. A detailed description of PVD is not provided here, as the process has been possible for some time using commercial machines.

It may be provided that the PVD coating and the surface structuring overlap each other in an overlapping region, and the elastomer coating is provided at least or only in the overlapping region of the PVD coating and the surface structuring. The PVD coating can lead to a further improvement in the adhesion of the elastomer coating.

According to one example, the PVD coating is arranged on the surface structuring. In this case, the surface structuring can be created first and then the PVD coating can be applied to the surface structuring. In another example, the channel-shaped depressions of the surface structuring form at least partial interruptions in the PVD coating. In this case, the metal layer can be coated with the PVD coating, after which the channel-shaped depressions are created using the laser.

The channel-shaped depressions can, for example, be linear, optionally rectilinear. The channel-shaped depressions can run parallel to each other at least in sections, intersect and/or form a diamond-shaped grid structure. Alternatively, the depressions can be annular or spiral-shaped.

In this case, the channel-shaped depressions can be longer than wide, by at least a factor of 5, optionally a factor of 10.

The channel-shaped depressions often form a macro-structuring of the metal layer, wherein the metal layer has a micro-structuring within the channel-shaped depressions. Macro-structuring and/or micro-structuring can increase the surface area of the metal layer, allowing the elastomer coating to adhere better to the metal layer. Undercuts can also be formed within the channel-shaped depressions, for example mushroom-shaped undercuts into which the elastomer coating can penetrate. The adhesion can be further improved by the local form fit of the elastomer coating with the undercut. The undercuts can be part of the microstructuring.

In one embodiment, the channel-shaped depressions are at least partially surrounded, optionally laterally, by protrusions which are formed on the respective circumferential edge of the channel-shaped depressions. The respective protrusion can then protrude over the untreated surface of the metal layer and be formed from the material that has migrated from the channel-shaped depressions. In some embodiments, the protrusions may optionally also have a microstructuring. For example, the protrusions have a height of at most 30 μm or at most 20 μm in relation to the untreated surface of the metal layer. It may be provided that a depth of the channel-shaped depressions in relation to the untreated surface of the metal layer is at least 7 μm and/or at most 50 μm, and/or wherein a width of the channel-shaped depressions is at least 35 μm and/or at most 150 μm, and/or wherein a layer thickness of the PVD coating is at least 100 nm and/or at most 1 μm, and/or wherein a layer thickness of the elastomer coating is at least 10 μm and/or at most 3 mm. Parallel depressions can be at least 1.5 times the width of the depression and/or at most 3 mm apart. If two or more channel-shaped depressions intersect, a depth at the intersection of the depressions can be greater, e.g. at least 1.5 times or 2 times greater than the depth of a single channel-shaped depression.

The metal layer is usually made of titanium or stainless steel, for example stainless steel 1.4404 or 1.4541. The metal layer can be made at least predominantly or completely from these materials. However, the present disclosure is not limited to these materials.

The PVD coating can comprise at least one layer, for example two layers. If more than one layer is provided, the layers usually differ in terms of their materials. The PVD coating can comprise or consist of at least one of the following materials: titanium, nickel, niobium, tantalum, carbon, platinum, zirconium, carbide, titanium nitride, titanium aluminum nitride and/or titanium carbonitride. However, the present disclosure is not limited to these materials.

The elastomer coating can also comprise or consist of FKM (fluoroelastomer), silicone rubber or NBR rubber (nitrile-butadiene rubber), PUR (polyurethane), NR (natural rubber), FFKM (perfluoro rubber), SBR (styrene-butadiene rubber), BR (butadiene rubber), FVMQ (fluorosilicone), CSM (chlorosulfonated polyethylene), HNBR (hydrogenated nitrile-butadiene rubber), ACM (acrylate rubber), AEM (acrylate-ethylene rubber), EPDM (ethylene-propylene-diene rubber), IIR (butyl rubber) or mixtures of the aforementioned substances. However, the present disclosure is not limited to these materials.

The separator plate often has at least one through-opening for passing a reaction medium or product medium and/or at least one flow field for guiding the reaction medium or product medium along the separator plate. As a rule, the elastomer coating is arranged around the through-opening and/or the flow field to seal the through-opening and/or the flow field. The desired electrolytic reaction typically takes place in the region of the flow field, for example the splitting of water into hydrogen and oxygen. The flow field can optionally have channel structures. The channel structures of the flow field are usually integrally formed in the separator plate, for example by means of embossing, hydroforming or deep-drawing.

The separator plate may be designed as a bipolar plate. In other words, the separator plate in a stack of electrochemical cells connected in series can form the anode of a first electrochemical cell on one side and the cathode of a second electrochemical cell adjacent to the first electrochemical cell on the other side.

According to a further aspect, an electrolyser is provided, wherein the electrolyser comprises a plurality of stacked separator plates of the type described above. A membrane electrode assembly (MEA) and/or a porous transport layer (PTL) or gas diffusion layer (GDL), which is arranged between the MEA and the separator plate, can also be provided for each separator plate.

According to a further aspect, a method for manufacturing a separator plate for an electrolyser is provided. The method comprises at least the following steps:
creating a surface structuring in a metal layer by irradiating the layer with a laser, wherein the surface structuring comprises a plurality of channel-shaped depressions,
applying an elastomer coating to the metal layer, at least in the region of the surface structuring.

The elastomer coating is designed as a sealing element for sealing at least one region of the separator plate.

The method can also have a further step: applying a PVD coating to the metal layer, wherein the elastomer coating is applied to the metal layer in the region of the PVD coating.

The surface structuring and the PVD coating can overlap each other in an overlapping region. The elastomer coating is usually applied at least to the overlapping region. In one embodiment, the metal layer is first provided with the PVD coating and then laser surface-treated at least in this region to create the surface structuring. Alternatively, the metal layer is first laser surface-treated to create the surface structuring. The metal layer is then provided with the PVD coating, at least in this region.

The method described here is particularly suitable for producing the separator plate described above or is designed for this purpose. Features that have only been described in connection with the separator plate can be combined with the method and vice versa.

Embodiments of the separator plate, the arrangement and the electrochemical system are shown in the attached figures and are explained in more detail in the following description.

### BRIEF DESCRIPTION OF THE FIGURES

FIG. 1 shows an exploded view of an individual cell of an electrolyser, comprising a separator plate according to the present disclosure.

FIG. 2 shows a top view of a metal layer of a separator plate according to one embodiment.

FIG. 3 shows a cross-section through a partial area of the separator plate as shown in FIG. 2.

FIG. 4 shows a cross-section through a section of another separator plate.

FIG. 5 shows a cross-section through a section of another separator plate.

FIG. 6 shows a laser surface-treated test specimen.

FIG. 7 to FIG. 11 show various surface structurings.

FIG. 12 shows an SEM image of a surface structuring.

FIG. 13 shows another SEM image of a surface structuring.

FIG. 14 shows a cross-section through a part of a separator plate in a further embodiment.

FIG. 15 shows a detailed view of section A in FIG. 14.

### DETAILED DESCRIPTION

Here and in the following, recurring features in different figures are each designated with the same or similar reference signs.

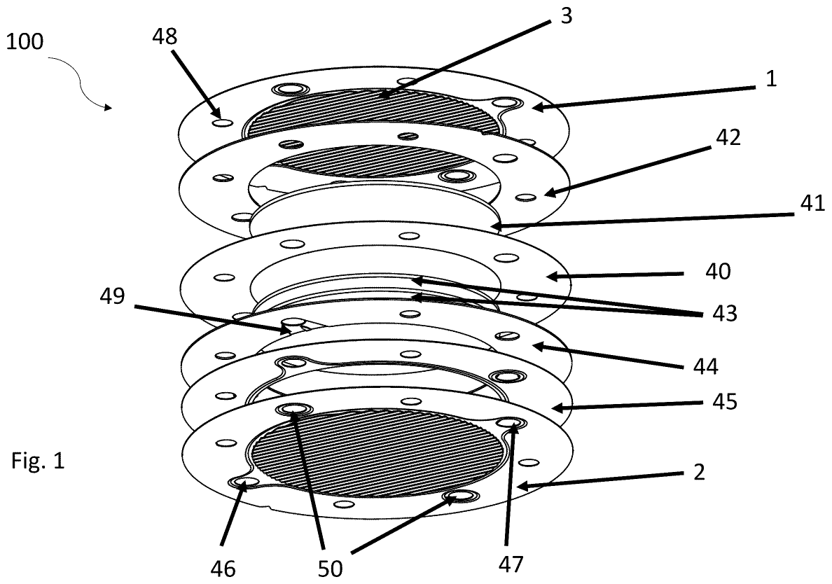

FIG. 1 shows an exploded view of an individual electrochemical cell 100, wherein the cell 100 is part of an electrolyser. Electrolysers typically comprise a large number of stacked individual cells 100. The individual cell 100 comprises two separator plates 1 and 2, two cell frames 42 and 44, a sealing layer 45, and a membrane electrode assembly 40 with media diffusion structures 41 and 43. For example, the media diffusion structure 43 comprises layers of carbon fleece, while the media diffusion structure 41 comprises metal, e.g. titanium. Here, the separator plate 1 is arranged, for example, on the anode side of the individual cell 100. In the exemplary embodiment shown, the separator plate 2 is arranged on the cathode side of the individual cell 100. The individual layers are compressed together to form an individual cell. The individual layers each have fluid passages 46, 47, 50, arranged in alignment one above the other, for the inward and outward passage of water, oxygen and hydrogen, as well as positioning holes 48.

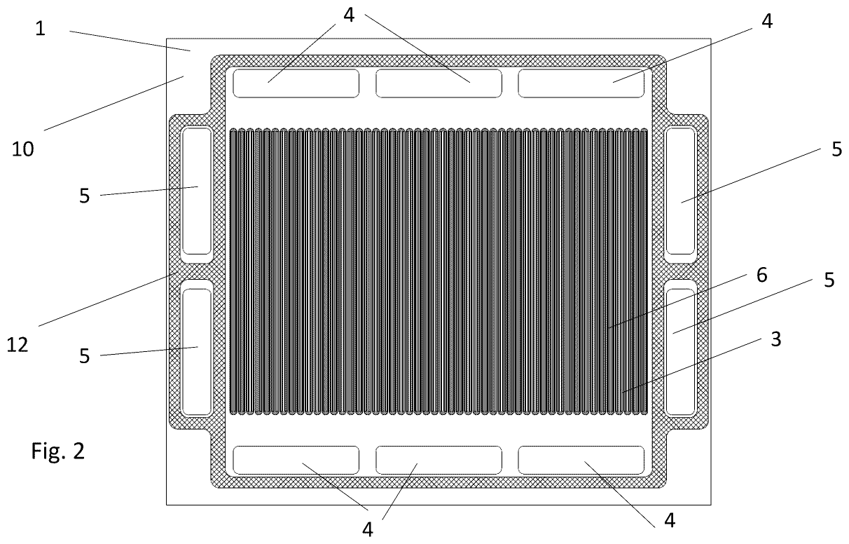

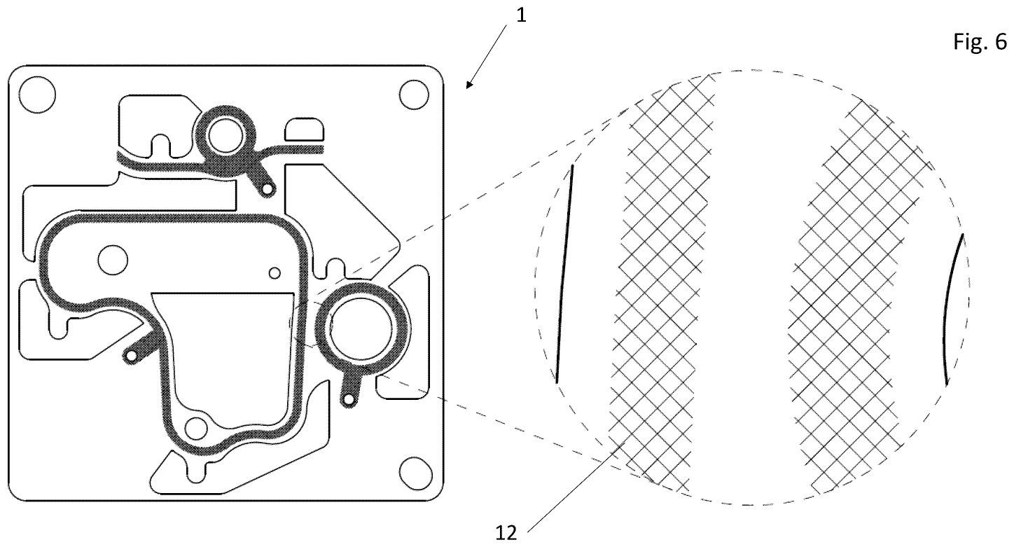

A flow field of the separator plate 2 is defined by projecting the cell frame 44 onto the separator plate 2. A flow field 3 of the separator plate 1 is defined by projecting the cell frame 42 onto the separator plate 1. The cell frame 42 has distribution channels (not shown) for distributing the water that is fed in. The through-openings 46, 47 are fluidically connected to the flow field 3 so that a medium can be routed from the through-opening 46 to the flow field 3, or from the flow field 3 to the through-opening 47. When a potential is applied, hydrogen (or oxygen) can be generated in the electrolyser from the supplied water. This can be discharged through the distribution channels 49 in the cell frame 44. It can then leave the cell through the through-openings 50. While the separator plates 1 shown in FIG. 1 have a round outer contour, other shapes are also possible. For example, the separator plates 1, 2 can have a rectangular outer contour (see also FIGS. 2 and 6).

The separator plates 1, 2 in FIG. 1 are exemplary separator plates according to the prior art.

As already indicated above, a pressure difference between the environment and the interior of the electrochemical cell 100 can be more than 20 bar. The pressure on the product side, for example the hydrogen side, is often up to 40 bar, while the pressure on the reactant side, for example the water side, is only up to 2 bar. Sealing structures are therefore provided to seal the individual regions from each other.

For example, elastomer seals are used, which are arranged around the regions to be sealed. So that the elastomeric material can be bonded to the metal layer of the separator plate 1, the metal layer is first coated with an adhesion promoter as a one-layer system or with a primer and an adhesion promoter as a two-layer system. This one coating or these coatings are usually over the entire surface, while the elastomer coating is usually not over the entire surface, but only in the regions of the separator plate to be sealed. In addition, the primer/adhesion promoter impairs the necessary electrical conductivity in the active regions of the separator plate and would therefore have to be removed again in the active regions, i.e. in the flow field.

The present disclosure was conceived to solve these problems, at least in part.

In particular, it was recognized that a laser surface structuring and/or a PVD coating can serve as a suitable substrate for applying an elastomer coating. This significantly improves the adhesion of an elastomer coating applied to the laser surface structuring. The present disclosure is explained further below with reference to FIGS. 2-9.

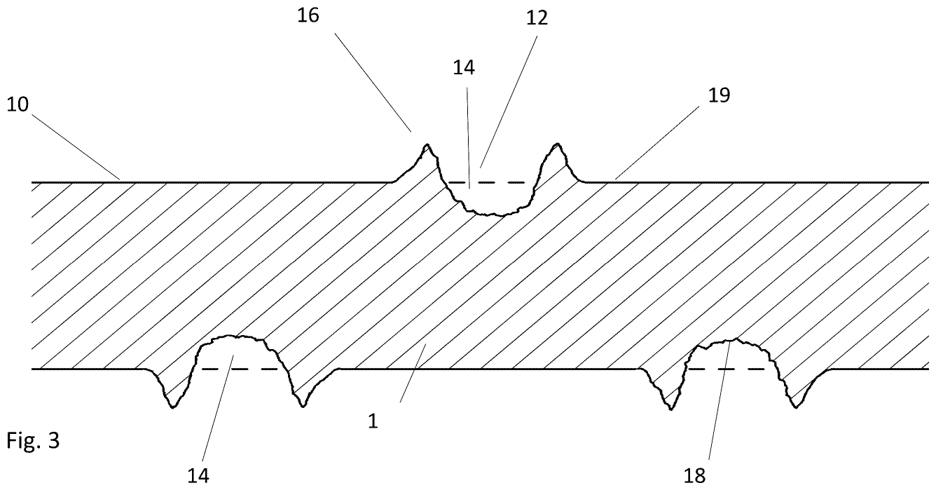

FIG. 2 shows a separator plate 1 for an electrolyser. FIG. 3 shows a section through a partial region of the separator plate 1 of FIG. 2. The separator plate 1 comprises a metal layer 10, which for example consists at least predominantly or completely of titanium or stainless steel. The metal layer 10 can have a thickness of at least 0.1 mm and/or at most 1 mm. The separator plate 1 has a flow field 3, which is designed to distribute the water supplied from the through opening 4 over as large an area as possible. Optional channel structures 6 are provided in the flow field 3 for this purpose. The through-opening 5 is designed to discharge hydrogen, wherein on the side of the separator plate shown the fluid through-openings 5 are surrounded by a surface structuring 12 according to the present disclosure and can be sealed off from the environment by means of a seal after coating with an elastomer (see below).

Sections of the metal layer 10 have a surface structuring 12. The surface structuring 12 in turn has a large number of channel-shaped depressions 14 produced by laser surface treatment. The depressions 14 are created by irradiating the metal layer 10 with a laser. A depth of the channel-shaped depressions 14 in relation to an untreated surface 19 of the metal layer 10 is, for example, at least 7 μm and/or at most 50 μm. In FIG. 3, the untreated surface 19 of the metal layer 10 is indicated by a dashed line in the region of the depressions 14. For the purposes of the present document, channel-shaped means that a length of the depressions is substantially greater than a width of the depressions, for example at least 5 times, at least 10 times or at least 20 times greater. The length of a depression is defined as the largest extent of the depression, for example in the processing direction or feed direction of the laser.

A width of the channel-shaped depressions 14 can be at least 35 μm and/or at most 150 μm. The width is often measured at half the height of the depressions 14. A width of the depressions 14 generally depends on a diameter of a laser spot used to create the depressions 14. The length of the depressions, on the other hand, does not depend on the beam diameter of the laser used, but can be varied by moving the laser beam along the separator plate 1 or by moving the component, see FIGS. 6-11. The ratio of the width to the depth of the channel-shaped depressions can be approximately 1.5 to 7. This means that the channel-shaped depressions are wider rather than deeper.

It may be provided that the channel-shaped depressions 14 are surrounded by protrusions 16, which are formed on the respective circumferential edge of the channel-shaped depressions 14, see FIG. 3. The respective protrusion 16 can protrude above the untreated surface 19 of the metal layer 10 and is formed, for example, from the material that has migrated from the channel-shaped depressions 14. If the protrusions are provided and/or the untreated surface 19 of the metal layer 10 has unevenness and a determination of the depth of the depressions 14 in relation to the untreated surface 19 of the metal layer should be difficult, the height of the protrusions 16 can be taken into account in the above indication of the depth of the depressions 14, that is, if protrusions 16 should be present around the depressions 14, the depth of the depression 14 is indicated from the apex of the protrusion 16 to the deepest point of the depression 14.

The channel-shaped depressions 14 usually form a macro-structuring of the metal layer 10, wherein the metal layer 10 has a micro-structuring 18 within the channel-shaped depressions 14. The macrostructuring can be understood as the outline of the channel-shaped depressions 14, while the microstructuring extends within the depressions 14. Compared to the untreated surface 19 of the metal layer 10, the microstructuring 18 has a greater surface roughness, which favors the adhesion of the elastomer seal 20 to the metal layer 10. The protrusions 16 can also have a microstructuring 18. Typically, the protrusions have a height of at most 30 μm in relation to the untreated surface 19 of the metal layer 10. Undercuts can also be formed within the channel-shaped depressions 14, for example mushroom-shaped undercuts into which the still liquid elastomer compound can penetrate. After the elastomer compound has solidified to form the elastomer coating 20 and through the local form fit of the elastomer coating 20 with the undercut, the adhesion can be further improved. The undercuts can be part of the microstructuring (micro undercut).

FIGS. 6-11 show different types of surface structuring 12 of the metal layer 10. Various macrostructures of the channel-shaped depressions 14 can be seen here. Accordingly, the channel-shaped depressions 14 can be linear, for example rectilinear or curved, see FIGS. 6-11.

The region in which the surface structuring 12 is provided can extend in a band along the separator plate 1 or the region of the separator plate 1 to be sealed. The width of this region can be at least 0.5 mm and/or at most 10 mm. Furthermore, this region can be self-contained or even full-surface and can optionally not protrude beyond the elastomer coating.

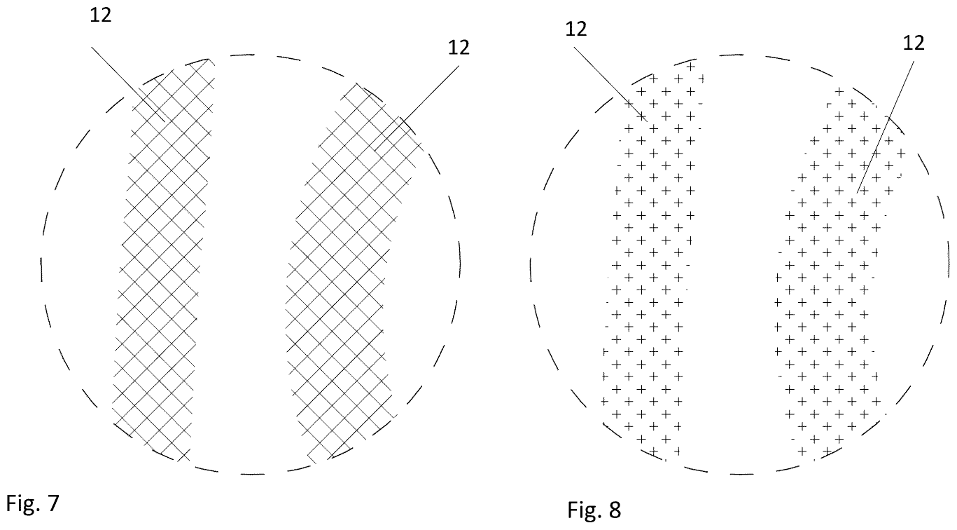

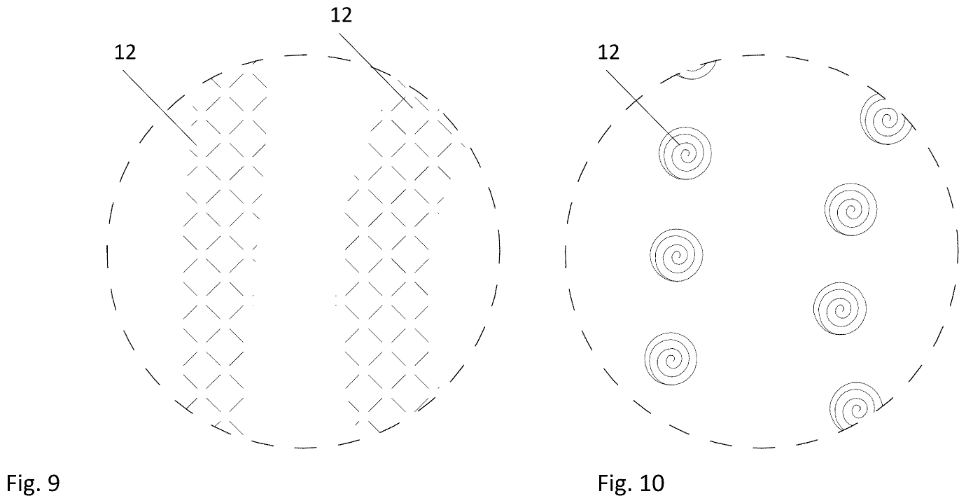

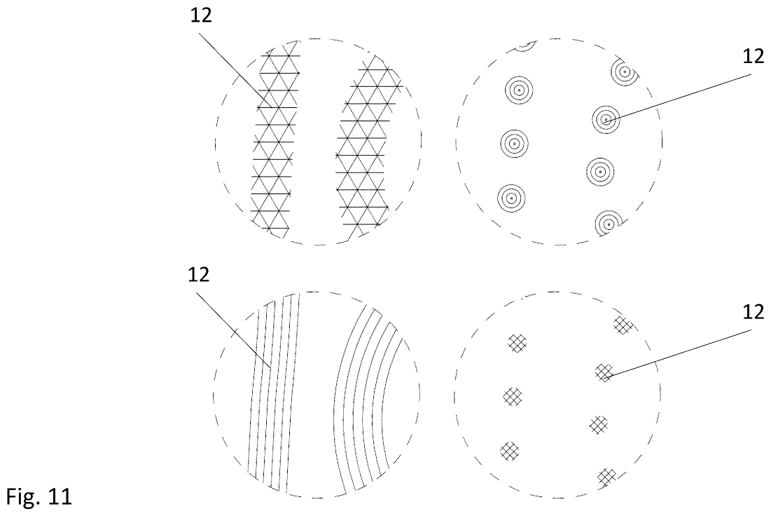

In FIGS. 7 and 8, there are a plurality of depressions 14 which run parallel to one another, at least in sections. There are also depressions 14 that are arranged at an angle to each other. In FIGS. 7 and 8, the angle is approximately 90°, although other angles—smaller or larger—are also possible. Depressions arranged at an angle to each other can intersect (see FIGS. 7 and 8) and form a diamond-shaped grid structure (see FIG. 7) or a honeycomb-shaped grid structure (see FIG. 11 top left). The depressions 14 in FIG. 9 are spaced apart.

In FIGS. 10 and 11 (top right), the depressions extend in a spiral or ring shape. Further variations of the channel-shaped depressions are conceivable and the present disclosure is not limited to the shapes of the depressions 14 shown.

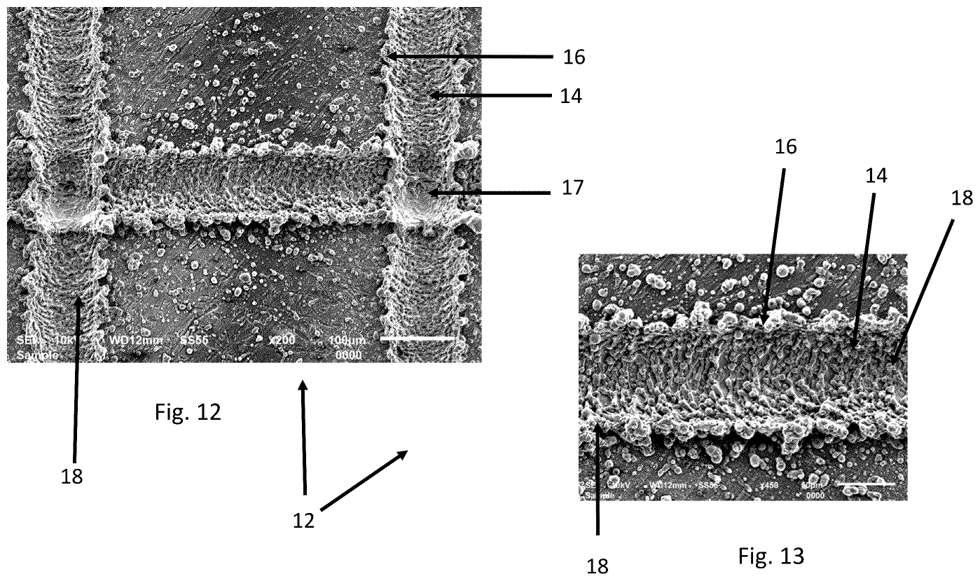

FIGS. 12 and 13 show images of depressions 14, which were made using scanning electron microscopy (SEM). The microstructuring 18 within the depressions 14 can be clearly seen in these figures. In addition, the protrusions 16 arranged on both sides of the depressions 14, which delimit the depressions 14, can also be seen. FIG. 12 also shows a crossing point 17 of intersecting channel-shaped depressions 14. At the intersection point 17, the depth of the depressions 14 can be greater than outside the intersection point 17. This is due to the fact that the metal layer 10 was irradiated twice with a laser beam in the region of the crossing point 17.

It should also be noted that parallel depressions 14 can be at least 1.5 times the width of the depression and/or at most 3 mm apart. In relation to the surface of the metal layer 10, which is provided with a surface structuring, approximately 20 to 90%, optionally 25 to 75%, can be provided with channel-shaped depressions.

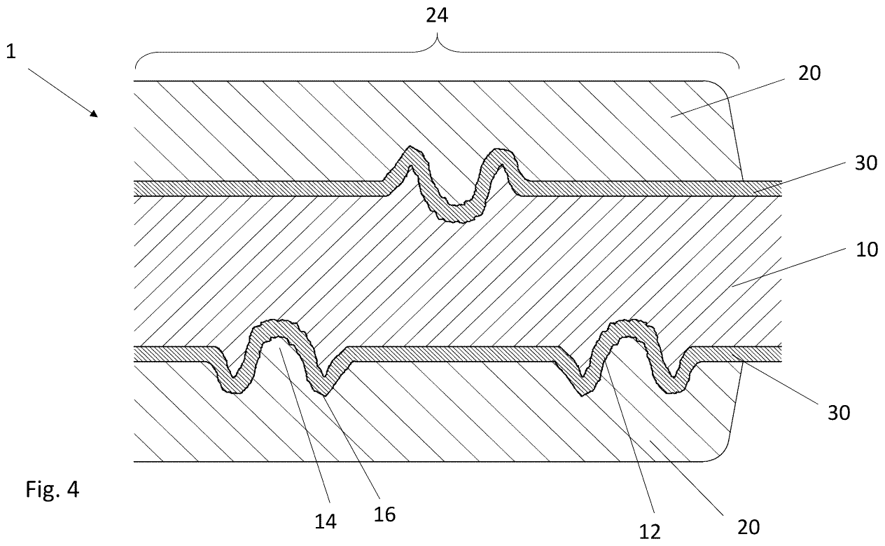

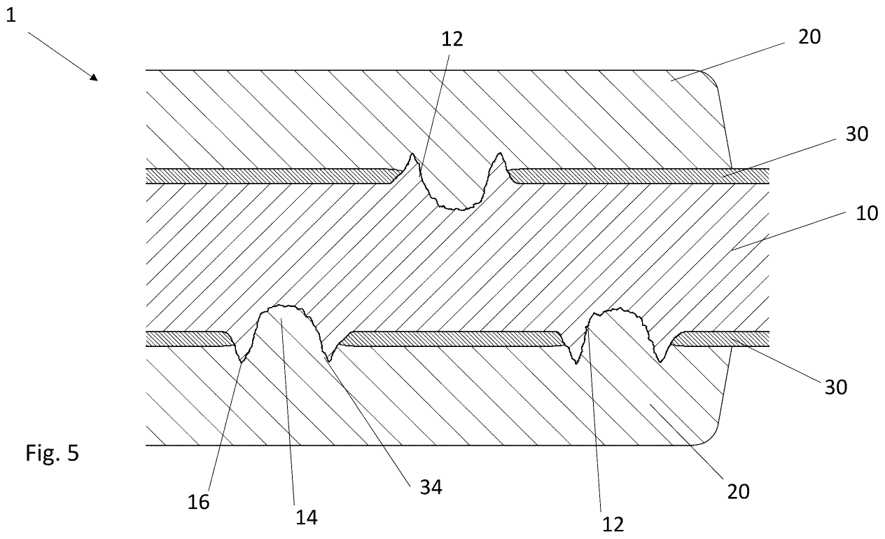

FIGS. 4 and 5 show similar sections through the separator plate 1 as in FIG. 3. The metal layers 10 of FIGS. 4 and 5 have the surface structuring 12 on both sides. However, the surface structuring 12 can also be provided on only one side of the metal layer 10.

As can also be seen in FIGS. 4 and 5, the separator plate 1 also has an elastomer coating 20 designed as a sealing element and applied to the metal layer 10 for sealing at least one region of the separator plate 1. The elastomer coating 20 is arranged at least on the surface structuring 12. The laser-treated surface in the region of the surface structuring is generally rougher than the untreated surface 19. This surface enlargement and increased roughness can therefore contribute to the elastomer seal 20 arranged in the region of the surface structuring 12 having a significantly improved adhesion than on the untreated surface 19.

A layer thickness of the elastomer coating 20 can, for example, be at least 10 μm and/or at most 3 mm. The layer thickness of the elastomer coating 20 can optionally be greater than the depth of the depressions 14, for example at least 2 times as great, or at least 10 times as great. The elastomer coating 20 should ideally be thick enough to sufficiently cover the raised areas of the surface structuring 12, for example any protrusions 16. The elastomer coating 20 can comprise or consist of, for example, FKM (fluoroelastomer), silicone rubber or NBR rubber (nitrile butadiene rubber), PUR (polyurethane), NR (natural rubber), FFKM (perfluoro rubber), SBR (styrene butadiene rubber), BR (butadiene rubber), FVMQ (fluorosilicone), CSM (chlorosulfonated polyethylene), HNBR (hydrogenated nitrile-butadiene rubber), ACM (acrylate rubber), AEM (acrylate-ethylene rubber), EPDM (ethylene-propylene-diene rubber), IIR (butyl rubber) or mixtures of the aforementioned substances.

The elastomer coating 20 designed as a sealing element can form a sealing contour or sealing line. As indicated in FIG. 2, the separator plate 1 can have at least one through-opening 47, in the example of FIG. 2 through-opening 5 as a hydrogen port, for passing a reaction medium or product medium and/or at least one flow field 3 for guiding the reaction medium or product medium along the separator plate 1. The elastomer coating 20 is arranged around the through-opening 47, 5 and/or the flow field 3 to seal the through-opening or the flow field 3.

Optionally, the separator plate 1 can have a PVD coating 30 applied to the metal layer 10, see FIGS. 4 and 5. The elastomer coating 20 is often arranged at least in some regions on the PVD coating 30, see FIGS. 4 and 5. The PVD coating 30 and the surface structuring 12 typically overlap each other in an overlapping region 24, wherein the elastomeric coating 20 is provided at least in the overlapping region 24 of the PVD coating 30 and the surface structuring 12. The PVD coating 30 can further increase the adhesion of the elastomer coating 20.

A layer thickness of the PVD coating 30 is typically significantly less than the layer thickness of the elastomer coating and can be at least 100 nm and/or at most 1 μm. It should be noted that the size ratios in FIGS. 4 and 5 do not necessarily correspond to reality; rather, the PVD coating 30 is shown exaggeratedly large for the sake of clarity. The arrangement of the surface structuring 12 and the PVD coating relative to each other depends on which surface treatment, i.e. laser surface treatment or application of the PVD coating, is carried out first. For example, the PVD coating 30 can be arranged on the surface structuring 12 (see FIG. 4) if the laser surface treatment is carried out first and then the PVD coating. Alternatively, the channel-shaped depressions 14 of the surface structuring 12 can at least partially form interruptions 34 in the PVD coating 30 (see FIG. 5) if the order of the surface treatment was reversed.

The PVD coating 30 can comprise at least one layer of at least one material, but also two layers of different materials. The PVD coating can comprise or consist of at least one of the following materials: titanium, nickel, niobium, tantalum, carbon, platinum, zirconium, carbide, titanium nitride, titanium aluminum nitride and/or titanium carbonitride.

The metal layers 10 of FIGS. 4 and 5 have the elastomer coating 20 and the PVD coating 30 on both sides. However, the elastomer coating 20 and the optional additional PVD coating 30 can also be provided on just one side of the metal layer 10.

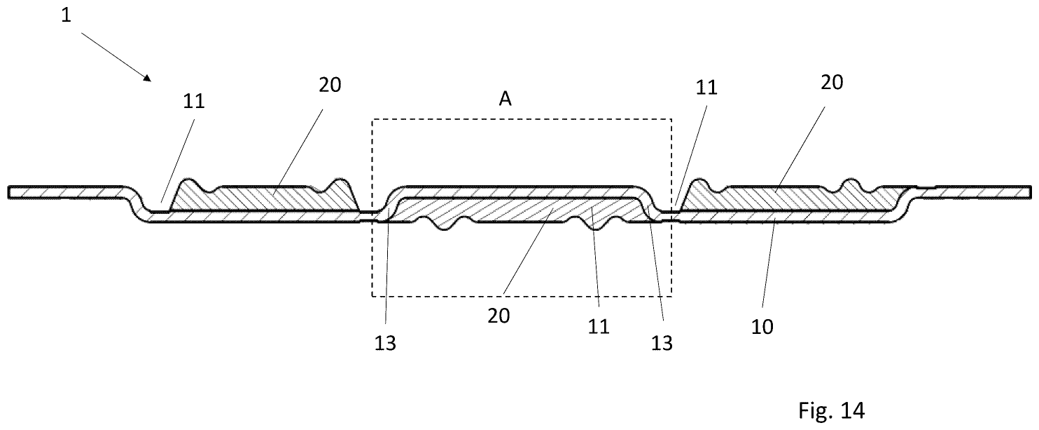

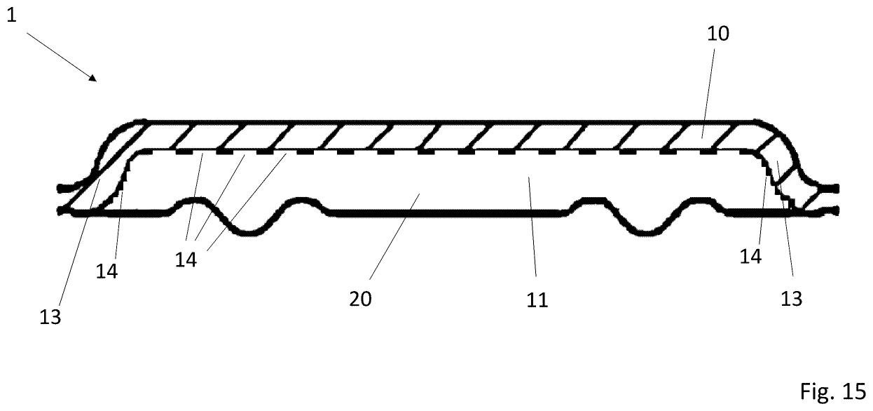

For direct comparison, reference is made here to an embodiment that largely corresponds to that in FIGS. 4 and 5. However, the metal layer 10 of FIGS. 14 and 15 does not have a PVD coating 30 but only an elastomer coating 20 on various sides of the metal layer 10 of the separator plate 1. When viewed parallel to the layer plane of the metal layer 10, the elastomer coatings 20 are arranged alternately in trench-like embossed depressions 11 that have been molded into the sealing region of the separator plate 1. The trench-like depressions 11 can be located at the same point on the separator plate 1 where the surface structuring 12 is shown in FIG. 2. In FIG. 2, this surface-structured region is flat. Now, in FIG. 14, this region is embossed several times along the course of the surface structuring 12. In these trench-like embossed recesses 11, which each accommodate an elastomer coating 20, a surface structure in the form of channel-shaped depressions 14 can now also be applied to the surface using a laser. In FIG. 15, these are symbolized in cross-section by an interrupted line of the surface at the bottom of the trench-like depression 11. There are also channel-like depressions 14 on the flanks of the trench-like depression 11 in FIG. 15, which can be distorted in perspective due to their arrangement on inclined surfaces, shown here in cross-section by a staircase shape. An embodiment is also conceivable in which the channel-shaped depressions 14 are provided exclusively on the inside of the flanks 13 of the trench-like recess 11. Variants in which an elastomer coating 20 is sprayed onto the inner edge of the fluid through-openings 4 and 5 are also conceivable. In these cases, an additional surface structuring 12 could be applied to the inner edge of these through-openings.

It is also possible to provide a sealing element consisting of elastomer coating 20 around the outer edge of the metal layer. In this case, a surface structuring 12 could be applied to the outer edge of the separator plate 1.

A method for manufacturing the separator plate 1 described above is also provided. The method comprises the following steps:
producing a surface structuring 12 in a metal layer 10 by irradiating the layer 10 with a laser, wherein the surface structuring 12 comprises a plurality of channel-shaped depressions 14,
applying an elastomer coating 20 to the metal layer 10 at least in the region of the surface structuring 12, the elastomer coating 20 being designed as a sealing element for sealing at least one region of the separator plate 1.

The choice of laser that can be used is not particularly limited. Any laser with sufficient power to create channel-shaped depressions 14 of a suitable size and depth in the material of the metal layer 10 can be used. Optionally, a pulsed laser is used as the laser beam source in the present disclosure. Solid-state lasers have proven to be particularly suitable here.

The laser can be a pulsed femto, pico or nanosecond laser, for example. Alternatively, cw lasers are also possible. The depressions are then formed by melting the material of the metal layer 10. Due to the heat generated as a result of the laser irradiation, very fine particles of metal or metal compounds are detached from the surface and are vaporized. The channel-shaped depressions 14 can then be created by scanning the metal layer with the laser spot. The surface treatment by means of laser radiation is advantageously carried out in such a way that the mechanical properties of the material of the metal layer are not damaged and the metal layer is not undesirably weakened.

The laser system used here can, for example, have a power of 20 to 200 watts laser at a wavelength of 1030 nm or 1062 nm, a focal length of 254 mm and an ablation rate of around 25 cm²/s. Details and exemplary laser parameters are shown in the following table:

| | | Energy | Pulse | Ablation | Travel |
|---|---|---|---|---|---|
| Power | Pulse rate | per pulse | duration | rate | speed |
| [W] | [kHz] | [mJ] | [ns] | [cm²/min] | [mm/s] |
| 20 | 28 | 70 | 190 | 40 | 150-250 |
| 200 | 200 | 100 | 500 | 144 | 1200-2400 |

Of course, other lasers or laser parameters are also suitable for creating the surface structuring 12 or depressions 14.

The elastomer coating can be applied or sprayed on using press molding, transfer molding or injection molding, for example. Such coating techniques are known from the prior art.

The method may comprise the additional step:

Applying a PVD coating 30 to the metal layer 10, the elastomer coating 20 being applied to the metal layer 10 in the region of the PVD coating 30.

Optionally, the metal layer 10 is first provided with the PVD coating 30. The metal layer is then laser surface-treated, at least in this region, to create the surface structuring 12. Alternatively, the metal layer 10 is first laser surface-treated to create the surface structuring 12 and then provided with the PVD coating 30, at least in this region.

The PVD coating can be applied to the metal layer 10 using conventional techniques. A detailed description is therefore not provided.

Individual features of the separator plates 1 and assemblies described above and shown in FIGS. 1-10 may be claimed separately or combined with each other, provided that the features being combined do not contradict each other.

### LIST OF REFERENCE SIGNS

1 separator plate
2 separator plate
3 flow field
4 through-opening for fluid
5 through-opening for fluid
6 channel structures
10 metal layer
11 trench-like embossed depressions
12 surface structuring
13 flanks of the trench-like embossed depressions
14 channel-shaped depressions
16 protrusions
17 intersection
18 microstructuring
19 untreated surface
20 elastomer coating
24 overlapping region
30 PVD coating
34 interruption of the PVD coating
40 membrane electrode assembly
41 media diffusion structure
42 cell frame
43 media diffusion structure
44 cell frame
45 sealing layer
46 through-opening for fluid
47 through-opening for fluid
48 positioning hole
49 hydrogen distribution channels
50 hydrogen through-openings

1. A separator plate for an electrolyser, comprising
a metal layer which has a surface structuring in sections, wherein the surface structuring comprises a plurality of channel-shaped depressions produced by laser surface treatment, and
an elastomer coating designed as a sealing element and applied to the metal layer for sealing at least one region of the separator plate,
wherein the elastomer coating is arranged at least in some regions on the surface structuring.

2. The separator plate according to claim 1, further comprising a PVD coating applied to the metal layer, wherein the elastomer coating is arranged at least in regions on the PVD coating.

3. The separator plate according to claim 2, wherein the PVD coating and the surface structuring overlap each other in an overlapping region, and the elastomer coating is provided at least in the overlapping region of the PVD coating and the surface structuring.

4. The separator plate according to claim 3, wherein
the PVD coating is arranged on the surface structuring or
the channel-shaped depressions of the surface structuring at least partially form interruptions in the PVD coating.

5. The separator plate according to claim 1, wherein the channel-shaped depressions are linear and run parallel to one another at least in sections, intersect, and/or form a diamond-shaped grid structure, or wherein the channel-shaped depressions are annular or spiral-shaped.

6. The separator plate according to claim 1, wherein the channel-shaped depressions form a macrostructuring of the metal layer, wherein the metal layer has a microstructuring within the channel-shaped depressions.

7. The separator plate according to claim 1, wherein the channel-shaped depressions are at least partially surrounded by protrusions which are formed on a respective circumferential edge of the channel-shaped depressions, wherein the protrusions project beyond an untreated surface of the metal layer and are formed from material migrated from the channel-shaped depressions, and wherein the protrusions have a microstructuring.

8. The separator plate according to claim 7, wherein the protrusions have a height (h) of at most 30 μm with respect to the untreated surface of the metal layer.

9. The separator plate according to claim 1,
wherein a depth of the channel-shaped depressions with respect to an untreated surface of the metal layer is at least 7 μm and/or at most 50 μm, and/or
wherein a width of the channel-shaped depressions is at least 35 μm and/or at most 150 μm, and/or
wherein a layer thickness of a PVD coating is at least 100 nm and/or at most 1 μm, and/or
wherein a layer thickness of the elastomer coating is at least 10 μm and/or at most 3 mm.

10. The separator plate according to claim 1, wherein parallel depressions have a distance to one another of at least 1.5 times the depression width and/or at most 3 mm.

11. The separator plate according to claim 1, wherein the metal layer is made of titanium or stainless steel.

12. The separator plate according to claim 2, wherein the PVD coating comprises at least one layer, and comprises at least one of the following materials: titanium, nickel, niobium, tantalum, carbon, platinum, zirconium, carbide, titanium nitride, titanium aluminum nitride and/or titanium carbonitride.

13. The separator plate according to claim 1, wherein the elastomer coating comprises or consists of FKM (fluoroelastomer), silicone rubber or NBR rubber (nitrile-butadiene rubber), PUR (polyurethane), NR (natural rubber), FFKM (perfluoro rubber), SBR (styrene-butadiene rubber), BR (butadiene rubber), FVMQ (fluorosilicone), CSM (chlorosulfonated polyethylene), HNBR (hydrogenated nitrile-butadiene rubber), ACM (acrylate rubber), AEM (acrylate-ethylene rubber), EPDM (ethylene-propylene-diene rubber), IIR (butyl rubber) or mixtures of the aforementioned substances.

14. The separator plate according to claim 1, further comprising
at least one through-opening for passage of a reaction medium or product medium and/or
at least one flow field for guiding the reaction medium or product medium along the separator plate,
wherein the elastomer coating for sealing the through-opening or the flow field is arranged around the through-opening and/or the flow field.

15. A method of manufacturing a separator plate for an electrolyser, comprising the steps of:
producing a surface structuring in a metal layer by irradiating the metal layer with a laser, wherein the surface structuring comprises a plurality of channel-shaped depressions, and
applying an elastomer coating to the metal layer at least in a region of the surface structuring, the elastomer coating being designed as a sealing element for sealing at least one region of the separator plate.

16. The method of claim 15, comprising the additional step of: applying a PVD coating to the metal layer, the elastomer coating being applied to the metal layer in a region of the PVD coating.

17. The method according to claim 16, wherein the surface structuring and the PVD coating overlap each other in an overlapping region, and the elastomer coating is applied at least to the overlapping region.

18. The method according to claim 16, wherein the metal layer is first provided with the PVD coating and is then laser surface-treated at least in this region to produce the surface structuring.

19. The method according to claim 16, wherein the metal layer is first laser surface-treated to produce the surface structuring and is then provided with the PVD coating at least in this region.

20. A method for manufacturing the separator plate according to claim 1.
